(19) United States
(12) Patent Application Publication
(10) Pub. No.: US 2022/0015269 A1
(43) Pub. Date: Jan. 13, 2022

(54) ENERGY-SAVING CONTAINER TYPE DATA CENTER

(71) Applicant: SHENZHEN ATTOM TECHNOLOGY CO., LTD., Shenzhen City (CN)

(72) Inventors: GANG XU, SHENZHEN CITY (CN); KUNLIANG WANG, SHENZHEN CITY (CN); HAIRONG DAI, SHENZHEN CITY (CN); MEISHENG HUANG, SHENZHEN CITY (CN); ZHIJUN TANG, SHENZHEN CITY (CN); LINGZHAO ZENG, SHENZHEN CITY (CN)

(21) Appl. No.: 17/145,722

(22) Filed: Jan. 11, 2021

(30) Foreign Application Priority Data
Jul. 10, 2020 (CN) 202010665050.7

(51) Int. Cl. H05K 7/20

(52) U.S. Cl. CPC H05K 7/20745; H05K 7/1488; H05K 7/20754; H05K 7/20836

(57) ABSTRACT

The invention relates to an energy-saving container-type data center, which adopts an integrated air-conditioning system. The integrated air-conditioning system can slide forward and backward along the mounting base of the container-type data center. The evaporator, condenser, compressor and the indoor fan and outdoor fan of the integrated air-conditioning system are integrated in an integrated physical frame. The outdoor fan described therein is an EC fan. An airflow management system is arranged in the container of the container-type data center, and the airflow management system isolates the cold and hot airflow in the container. The invention improves the installation time of the integrated air conditioning system, and the installation is convenient and efficient. The invention can adjust the speed output of the outdoor fan on demand according to the outdoor environment temperature and realize energy saving.

### CROSS-REFERENCE TO RELATED PATENT APPLICATION

This application claims the benefit of priority to China Patent Application No. 202010665050.7, filed on Jul. 10, 2020 in People's Republic of China. The entire content of the above identified application is incorporated herein by reference.

### FIELD OF THE DISCLOSURE

The invention belongs to the field of electronic information, and in particular relates to a container type data center.

### BACKGROUND OF THE DISCLOSURE

With the rapid development of the electronic information industry, the development of data centers has also entered a new stage. In the future, the edge data center is the first entry point for data. It is responsible for real-time business decision-making and short-term storage of large amounts of personal privacy data. It may be deployed in wireless base stations, rooftops, warehouses or other harsh working environments. Compatibility requirements will become more and more demanding. The containerized edge data center is a standard module built as a data center as a whole. It installs power, cooling, cabinets, computing, storage, network resources and other facilities into a container to realize product design, standardized production and de-engineering deployment. At present, while strengthening the basic management of the container-type data center, in order to maintain an ideal operating environment, it is necessary to cool down the IT equipment throughout the year, which brings huge power consumption and huge electricity expenses. The cooling of the existing container-type data center. The method mainly adopts conventional compressor-type mechanical refrigeration. The indoor fan of the air-conditioning system is separated from the outdoor extension in different installation spaces. The air-conditioning system needs to operate throughout the year and consumes a lot of energy. Therefore, it is necessary to design a container that can reduce energy consumption. Data center.

### SUMMARY OF THE DISCLOSURE

The technical problem to be solved by the present invention is to provide an energy-saving container-type data center capable of reducing energy consumption.

The technical solution adopted by the present invention to solve its technical problem is: an integrated air conditioning system is adopted, and the integrated air conditioning system can slide forward and backward along the mounting base of the container-type data center, and an indoor fan and outdoor fan of the integrated air conditioning system are integrated in an integrated physical frame.

Preferably, a distance that the integrated air conditioning system can slide forward and backward along the mounting base is not less than 200mm, an evaporator, condenser, compressor, and the indoor fan and outdoor fan of the integrated air conditioning system are integrated in the physical frame, and the outdoor fan is an EC fan.

Preferably, the integrated air conditioning system has three switchable operating modes, in which in a first mode, a compressor forms a circulation path with an condenser and an evaporator; in a second mode, the compressor, the condenser, a fluorine pump and the evaporator form the circulation path; and in a third mode: the condenser, fluorine pump and the evaporator form the circulation path.

Preferably, the integrated air-conditioning system is detachably mounted on the mounting base during transportation, and the integrated air-conditioning system and the mounting base are located in a container of the container-type data center, the mounting base and the container are detachably fixed, the side wall of the container of the container-type data center is provided with an air-conditioning sliding outlet at the position corresponding to the integrated air-conditioning system, and the air-conditioning sliding outlet is sealed by a sealing plate during transportation.

When in use, the sealing plate at the air-conditioning sliding outlet is removed, and the lower part of the air-conditioning sliding outlet is detachably mounted with an external mounting base, a transportation table of the external mounting base corresponds to a transportation table of the mounting base in the container to push the integrated air-conditioning system to slide from a transportation surface of the mounting base in the container to a transportation surface of the external mounting base.

Preferably, at least one of a rack system, an uninterrupted power supply and distribution system, a battery system, a firefighting system, an access security system, power environment monitoring system, video monitoring system, integrated wiring system, network communication system, IT equipment system are integrated in a space of the container of the container-type data center.

Preferably, the container-type data center includes cabinets, and the cabinets are configured to move forward and backward within a container of the container-type data center by a distance of not less than 100 mm.

Preferably, an airflow management system is arranged in a container of the container-type data center, and the airflow management system isolates a cold airflow from a hot airflow in the container.

Preferably, an air supply type of the integrated air-conditioning system is lower air supply and upper return air, and the airflow management system isolates an air supply vent of the lower air supply from a return air vent of the upper return air, and the cold air flow is enclosed in a space at a front of a cabinet, and the hot airflow flows from a rear of the cabinet through a top of the cabinet to the return air vent.

Preferably, an air supply type of the integrated air-conditioning system is lower air supply and upper return air, and the airflow management system includes a hot aisle cavity at a rear of a cabinet, a return air channel above the cabinet, and an airflow assembly connected to a return air vent of the upper return air, and the hot airflow at the rear of the cabinet flow to the air return vent through a top of the cabinet.

Preferably, an air supply type of the integrated air conditioning system is upper air supply and lower return air, the airflow management system isolates a return air vent of the lower return air from an air supply vent of the upper air supply, and the hot airflow is enclosed in a space at a rear of a cabinet, the hot airflow enters the return air vent from the rear of the cabinet, and the cold air flow from the air supply vent enters a front of the cabinet through a top of the cabinet.

Preferably, an air supply type of the integrated air-conditioning system is upper air supply and lower return air, and the air flow management system includes a cold aisle cavity at a front of a cabinet, an air supply channel above the cabinet, and an airflow assembly connected to an air supply vent of the upper air supply, and the cold airflow from the air supply vent flows to the front of the cabinet through a top of the cabinet.

The beneficial effects of the present invention are: the present invention adopts an integrated air conditioning system, which is more convenient and better to install. The integrated air conditioning system is slidable, and the installation is convenient and efficient. The outdoor fan of the present invention adopts an EC fan, which can adjust the speed output of the outdoor fan as required according to the outdoor environment temperature, thereby realizing energy saving. The integrated air-conditioning system of the present invention can utilize the natural cold source of the external environment when the outdoor temperature is low, and can cool the container-type data center with less power when the outdoor temperature is low. An air flow management system is provided in the container of the container-type data center. The air flow management system forms relatively isolated cold aisles and hot aisles in the container, reducing energy loss caused by the mixing of cold and hot air flows.

### BRIEF DESCRIPTION OF THE DRAWINGS

The present invention will be further explained below in conjunction with the drawings.

FIGS. 1A and 1B are schematic diagrams of the connection of the integrated air conditioning system in the present invention.

FIG. 2 is a schematic diagram of the cold aisle partition when the air supply type of the air conditioning system is the lower air supply and the upper return air.

FIG. 3 is a schematic diagram of the hot aisle partition when the air supply type of the air conditioning system is the lower air supply and the upper return air.

FIG. 4 is a schematic diagram of the cold aisle partition when the air supply type of the air conditioning system is upper air supply and lower return air.

FIG. 5 is a schematic diagram of the hot aisle partition when the air supply type of the air conditioning system is upper air supply and lower return air.

FIG. 6 is a structural diagram of the integrated air conditioning system in the container during transportation.

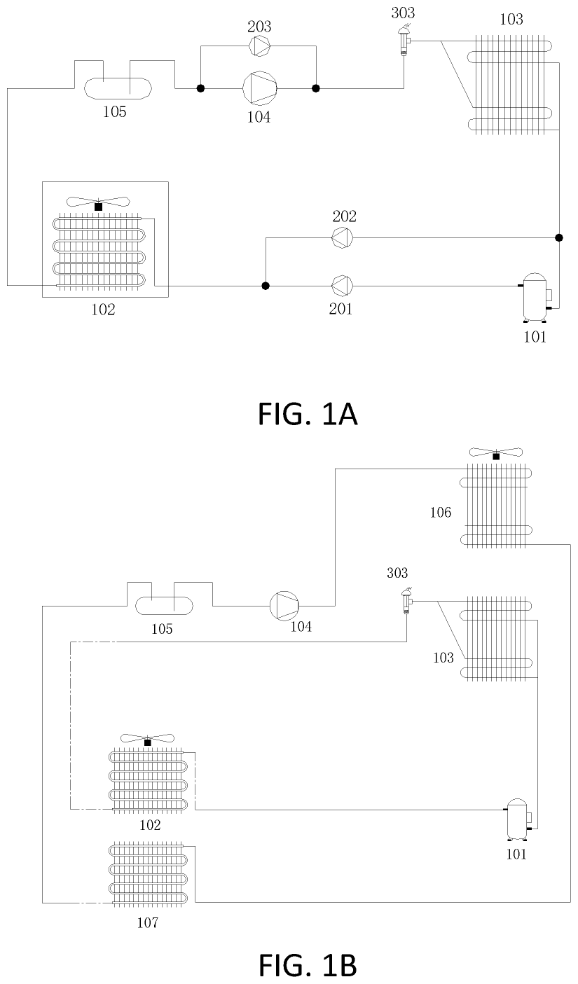

Among them: 501, integrated air conditioning system, 502, container, 503, cabinet; 504, mounting base, 101, compressor, 102 condenser, 103 evaporator, 104, fluorine pump, 105, liquid storage tank, 201, first one-way valve, 202, second one-way valve, 203, third one-way valve, 303, electronic expansion valve, 106, fluorine pump indoor heat exchanger, 107, fluorine pump outdoor heat exchanger.

### DETAILED DESCRIPTION OF THE EXEMPLARY EMBODIMENTS

The present invention will now be further explained in conjunction with the drawings. These drawings are simplified schematic diagrams only to illustrate the basic structure of the present invention in a schematic way, so they only show the structure related to the present invention.

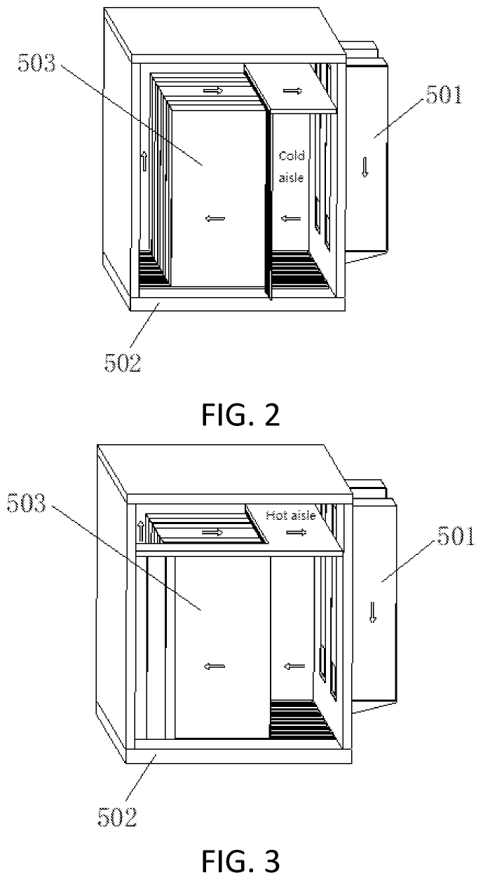

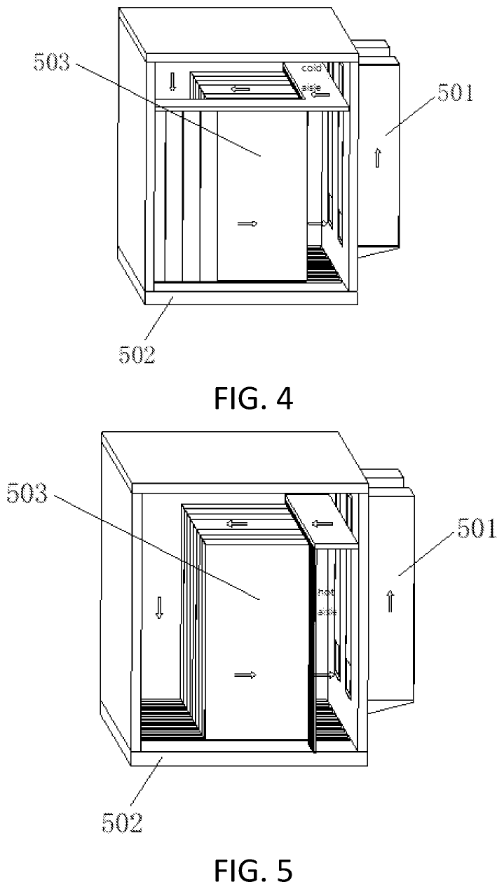

As shown in FIG. 2, FIG. 3, FIG. 4, and FIG. 5, an energy-saving container-type data center adopts an integrated air conditioning system 501. The integrated air conditioning system 501 can be mounted along the front of the base of the container-type data center, and the integrated air conditioning system 501 slides forward and backward along a mounting base of the container-type data center. Preferably, the distance that the integrated air conditioning system 501 can slide forward and backward along the mounting base that is not less than 200 mm. Preferably, the evaporator, condenser, compressor, indoor fan and outdoor fan of the integrated air conditioning system 501 are integrated in an integrated physical frame. Preferably, the outdoor fan is an EC fan. Using EC fans, the speed output of the outdoor fans can be adjusted according to the outdoor ambient temperature as needed to achieve energy saving.

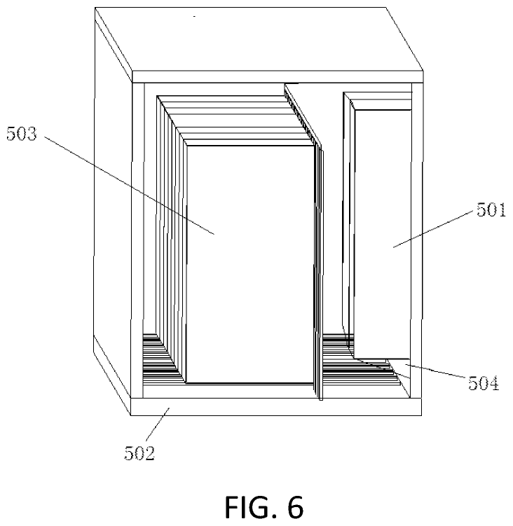

As shown in FIG. 6, during transportation, the integrated air conditioning system 501 can be detachably mounted on the mounting base 504. The integrated air conditioning system 501 and the mounting base 504 are located in the container 502 of the container-type data center. The mounting base 504 and the container 502 are detachable and fixed. Preferably, the mounting base 504 can also be supported in the container 502 through a support frame; the side wall of the container 502 of the container-type data center is provided with an air-conditioning sliding outlet at a position corresponding to the integrated air conditioning system 501. The sliding exit of the air conditioner is sealed by a sealing plate during transportation.

When in use, the sealing plate at the air-conditioning sliding outlet is removed, and the lower part of the air-conditioning sliding outlet can be detachably mounted with an external mounting base. The transportation table of the external mounting base corresponds to the transportation table of the mounting base 504 in the container 502, and pushes together. The air conditioning system 501 is modified so that it slides from the transportation platform of the mounting base 504 in the container 502 to the transportation platform of the external mounting base. Then, the integrated air conditioning system 501 is fixedly mounted with the container 502, and the external mounting base and the mounting base 504 and the support frame in the container 502 are removed. More preferably, a sliding cushion can be laid on the transportation table of the external mounting base and/or the transportation table of the mounting base 504 in the container 502, which is more convenient to push the integrated air conditioning system 501 to slide.

Therefore, the integrated air-conditioning system only needs to be simply pushed from the transportation position to the use position to slide it to the fixed position, which improves the installation time of the integrated air-conditioning system and is convenient and efficient.

The container 502 of the container-type data center integrates at least one of a rack system, an uninterrupted power supply and distribution system, a battery system, a firefighting system, an access security system, power environment monitoring system, video monitoring system, integrated wiring system, network communication system, IT equipment system are integrated in a space of the container of the container-type data center.

The data center includes a cabinet 503, and preferably, the cabinet 503 is movable. Preferably, the cabinet 503 can move forward and backward within the container 502 for a distance not less than 100 mm. Preferably, the cabinet 503 is placed on a rail, the cabinet 503 can slide forward and backward on the rail, and the rail is on a shock-absorbing plastic belt. The cabinet 503 is movable so that the cabinet 503 can free up operating space inside the container 502. The container-type data center includes an energy consumption monitoring and management system that can monitor energy consumption data of the data center in the cabinet. The energy consumption monitoring and management system can manage and adjust the integrated air conditioning system 501 to optimize operating energy consumption of the integrated air conditioning system 501.

The integrated air conditioning system 501 has three switchable operation modes, in which in a first mode, a compressor forms a circulation path with an condenser and an evaporator; in a second mode, the compressor, the condenser, a fluorine pump and the evaporator form the circulation path; and in a third mode: the condenser, fluorine pump and the evaporator form the circulation path

The integrated air conditioning system 501 includes a compressor 101, a condenser 102, an evaporator 103, a fluorine pump 104, a first one-way valve 201, a second one-way valve 202, a third one-way valve 203, and a liquid storage tank 105. The inlet of the first one-way valve 201 is connected to the outlet of the compressor 101, the outlet of the first one-way valve 201 is connected to the inlet of the condenser 102, the flow direction of the first one-way valve 201 is from the outlet of the compressor 101 to the inlet of the condenser 102; the inlet of the second one-way valve 202 is connected to the outlet of the evaporator 103, and the outlet of the second one-way valve 202 is connected to the inlet of the condenser 102. The flow direction of the second one-way valve 202 is from the outlet of the evaporator 103 to the inlet of the condenser 102; the inlet of the third one-way valve 203 is connected to the outlet of the liquid storage tank 105, and the outlet of the third one-way valve 203 is connected to the inlet of the evaporator 103. The flow direction of the third one-way valve 203 is from the outlet of the liquid storage tank 105 to the inlet of the evaporator 103; the outlet of the liquid storage tank 105 is connected to the inlet of the fluorine pump 104, the outlet of the fluorine pump 104 is connected to the inlet of the evaporator 103; the outlet of the condenser 102 is connected to the inlet of the liquid storage tank 105, and the inlet of the compressor 101 is connected to the outlet of the evaporator 103. The inlet of the evaporator 103 is also provided with an electronic expansion valve 303 for adjusting the flow of refrigerant.

The first mode is the working mode of vapor compression refrigeration. In the first mode, the first one-way valve 201 and the third one-way valve 203 are opened, and the second one-way valve 202 is closed. The refrigerant flow path of the vapor compression refrigeration is: overheating the gaseous refrigerant going from the outlet of the evaporator 103 to the compressor 101, and then to the condenser 102 after compression. The liquid refrigerant from the outlet of the condenser 102 enters the liquid storage tank 105, and then enters the inlet of the evaporator 103 to achieve cooling circulating flow of working fluid. This mode is a conventional vapor compression refrigeration method and suitable for high outdoor temperature, such as outdoor temperature is higher than the preset mode temperature 1, for example, preferably, when the outdoor temperature is greater than or equal to 20° C., the integrated air conditioning system 501 enters the first mode to work.

When the outdoor temperature is lower than the preset mode temperature 1, for example, preferably, the outdoor temperature is less than 20° C., the integrated air conditioning system 501 enters the second mode to work, that is, the vapor compression refrigeration and the fluorine pump natural cooling are activated at the same time. The one-way valve 201 is opened, the second one-way valve 202 is closed, and the third one-way valve 203 is closed. The compressor 101, the condenser 102, the liquid storage tank 105, the fluorine pump 104, and the evaporator 103 form a circulation path, and vapor compression refrigeration and the fluorine pump 104 are activated at the same time as the natural cooling of the fluorine pump. The operating power of the fluorine pump 104 is relatively small, and the compressor 101 can also operate at low frequency, which can effectively reduce the operating load of the compressor 101, improve the energy efficiency coefficient, and achieve the purpose of energy saving.

When the outdoor temperature drops further and the outdoor temperature is lower than the preset mode temperature 2, for example, preferably, when the outdoor temperature is less than 10° C., the integrated air conditioning system 501 enters the third mode to work, and the fluorine pump works with natural cooling mode. The first one-way valve 201 is closed, the third one-way valve 203 is closed, and the second one-way valve 202 is opened. The refrigerant flow path for the natural cooling of the fluorine pump is: the outlet of the supercooled liquid refrigerant from the condenser 102 enters the liquid storage tank 105, and then enters the evaporator 103 through the fluorine pump 104 for heat absorption and evaporation. The refrigerant from the outlet of the evaporator 103 enters the inlet of the condenser 102 through the second one-way valve 202 to achieve cooling the circulating flow of the working fluid, so as to realize the refrigeration function of the air conditioning system. This mode is powered by the fluorine pump 104. The operating power of the fluorine pump 104 is much lower than that of the compressor 101. Especially in winter, when the outdoor temperature is low, the natural cold source of the external environment is used. Carrying out the circulation of the refrigerating medium through the fluorine pump 104 with much lower operating power can realize the cyclic refrigeration of the container data center.

The integrated air conditioning system category 2: 501 includes compressor 101, condenser 102, evaporator 103, fluorine pump 104, fluorine pump indoor heat exchanger 106, fluorine pump outdoor heat exchanger 107, and liquid storage tank 105. The inlet of the condenser 102 is connected to the outlet of the compressor 101, the inlet of the compressor 101 is connected to the outlet of the evaporator 103, and the inlet of the evaporator 103 is connected to the outlet of the condenser 102. An electronic expansion valve 303 for regulating the flow of refrigerant is also provided at the inlet. The outlet of the liquid storage tank 105 is connected to the inlet of the fluorine pump 104, the outlet of the fluorine pump 104 is connected to the inlet of the fluorine pump indoor heat exchanger 106, and the outlet of the fluorine pump indoor heat exchanger 106 is connected to the fluorine pump The inlet of the outdoor heat exchanger 107 is connected to the inlet of the fluorine pump 104.

Mode 1 is the working mode of vapor compression refrigeration. In mode 1, the refrigerant flow path of vapor compression refrigeration is: the superheated gaseous refrigerant flows from the outlet of the evaporator 103 to the compressor 101, compressed to the condenser 102, and condenses The liquid refrigerant from the outlet of the evaporator 102 enters the inlet of the evaporator 103 to realize the circulating flow of the refrigerant. This mode is a conventional vapor compression refrigeration method, suitable for high outdoor temperature, such as outdoor temperature is higher than the preset mode temperature 1, for example, preferably, when the outdoor temperature is greater than or equal to 20° C., the integrated air conditioning system 501 enters mode one to work.

When the outdoor temperature is lower than the preset mode temperature 1, for example, preferably, the outdoor temperature is less than 20° C., the integrated air conditioning system 501 enters the mode 2 to work, that is, the vapor compression refrigeration and the fluorine pump natural cooling are activated at the same time. Compression refrigeration and natural cooling of the fluorine pump are activated at the same time. The operating power of the fluorine pump 104 is relatively small. The compressor 101 can also operate at low frequency, which can effectively reduce the operating load of the compressor 101, improve the energy efficiency coefficient, and achieve the purpose of energy saving.

When the outdoor temperature drops further and the outdoor temperature is lower than the preset mode temperature 2, for example, preferably, when the outdoor temperature is less than 10° C., the integrated air conditioning system 501 enters mode 3 to work, and the fluorine pump works in natural cooling at this time In the fluorine pump natural cooling mode, the refrigerant flow path for natural cooling is: the supercooled liquid refrigerant enters the storage tank 105 from the outlet of the fluorine pump outdoor heat exchanger 107, and then enters the fluorine pump indoor heat exchanger 106 after passing through the fluorine pump 104 During the heat absorption and evaporation, the refrigerant from the outlet of the fluorine pump indoor heat exchanger 106 enters the inlet of the fluorine pump outdoor heat exchanger 107 to realize the circulating flow of the refrigerant, thereby realizing the cooling function of the air conditioning system. This mode is powered by the fluorine pump 104. The operating power of the fluorine pump 104 is much lower than that of the compressor 101. Especially in winter, when the outdoor temperature is low, the natural cold source of the external environment is used. Circulating refrigeration working fluid can realize the cyclic refrigeration of the container-type data center.

Preferably, an airflow management system is provided in the container 502 of the container-type data center, and the airflow management system isolates the cold and hot airflow in the container 502. The airflow management system makes relatively isolated cold and hot aisles formed in the container 502, reducing energy loss caused by the mixing of cold and hot airflows.

As shown in FIG. 2, the hollow arrow directions in FIGS. 2, 3, 4, and 5 are the airflow directions. The air supply type of the integrated air conditioning system 501 is lower air supply and upper return air. The air management system isolates the air supply opening of the lower air supply and the return air return of the upper return air, and seals the cold air flow in the space at the front of the cabinet 503, the hot air flows from the rear of the cabinet 503, passes through the top of the cabinet 503, and returns to the air return vent.

As shown in FIG. 3, the air supply type of the integrated air conditioning system 501 is lower air supply and upper return air. The air management system includes a hot aisle cavity mounted at the rear of the cabinet 503 and the return air channel and the air flow components that are connected to the upper return air return air outlet. The hot air at the rear of the cabinet 503 is sent to the return air outlet through the top of the cabinet 503.

As shown in FIG. 4, the air supply type of the integrated air conditioning system 501 is upper air supply and lower return air. The air flow management system isolates the return air outlet of the lower return air from the air supply outlet of the upper air supply. The hot air flow is enclosed in the space at the rear of the cabinet 503, the hot air enters the return air vent from the rear of the cabinet 503, and the cold air flow from the air supply vent enters the front of the cabinet through the top of the cabinet 503.

As shown in FIG. 5, the air supply type of the integrated air conditioning system 501 is upper air supply and lower return air. The air flow management system includes a cold aisle cavity mounted in the front of the cabinet 503 and the air supply channel and the air flow components that are connected to the upper air supply outlet. The cold air flow from the air supply outlet is sent to the front of the cabinet 503 through the top of the cabinet 503.

Preferably, an airflow baffle is arranged in the container 502, and the inner wall of the cabinet corresponding to the front of the cabinet 503 is provided with a return air outlet and an air outlet. The return air vent is located at the upper part and the air outlet is located at the lower part, or the return air vent is located at the lower part and the air outlet is located at the upper part. The airflow baffle separates the air supply opening and the return air opening. A front airflow baffle is added to the front of the cabinet 503. The airflow baffle is erected between the top of the front airflow baffle and the inner wall of the cabinet corresponding to the front of the cabinet. When the air return port is located at the upper part and the air outlet is located at the lower part, a cold aisle is formed below the airflow baffle and in front of the front airflow baffle to reduce the mixing of cold and hot airflow. When the return air vent is at the lower part and the air outlet is at the upper part, a hot aisle is formed below the airflow baffle and in front of the front airflow baffle, reducing the mixing of cold and hot airflow.

Preferably, a rear airflow baffle is added to the rear of the cabinet 503, and the rear airflow baffle is placed between the edge of the rear of the cabinet and the inner wall of the cabinet corresponding to the rear of the cabinet. Preferably, the airflow baffle is L-shaped partition. When the return air vent is located at the upper part and the air outlet is located at the lower part, a hot aisle is formed above the airflow partition to reduce the mixing of cold and hot airflow. When the return air vent is at the lower part and the air outlet is at the upper part, a cold aisle is formed above the airflow partition to reduce the mixing of cold and hot airflow.

Taking the above-mentioned ideal embodiment according to the present invention as enlightenment, through the above-mentioned description content, relevant staff can make various changes and modifications without departing from the scope of the technical idea of the present invention. The technical scope of this invention is not limited to the content of the description, and its technical scope must be determined according to the scope of the claims.

What is claimed is:

1. An energy-saving container-type data center is characterized in that: an integrated air conditioning system is adopted, and the integrated air conditioning system can slide forward and backward along the mounting base of the container-type data center, and an indoor fan and outdoor fan of the integrated air conditioning system are integrated in an integrated physical frame.

2. The energy-saving container-type data center according to claim 1, wherein a distance that the integrated air conditioning system can slide forward and backward along the mounting base is not less than 200mm, an evaporator, condenser, compressor, and the indoor fan and outdoor fan of the integrated air conditioning system are integrated in the physical frame, and the outdoor fan is an EC fan.

3. The energy-saving container-type data center according to claim 1, wherein the integrated air conditioning system has three switchable operating modes, in which in a first mode, a compressor forms a circulation path with an condenser and an evaporator; in a second mode, the compressor, the condenser, a fluorine pump and the evaporator form the circulation path; and in a third mode: the condenser, fluorine pump and the evaporator form the circulation path.

4. The energy-saving container-type data center according to claim 1, wherein the integrated air-conditioning system is detachably mounted on the mounting base during transportation, and the integrated air-conditioning system and the mounting base are located in a container of the container-type data center, the mounting base and the container are detachably fixed, the side wall of the container of the container-type data center is provided with an air-conditioning sliding outlet at the position corresponding to the integrated air-conditioning system, and the air-conditioning sliding outlet is sealed by a sealing plate during transportation;
wherein in use, the sealing plate at the air-conditioning sliding outlet is removed, and the lower part of the air-conditioning sliding outlet is detachably mounted with an external mounting base, a transportation table of the external mounting base corresponds to a transportation table of the mounting base in the container to push the integrated air-conditioning system to slide from a transportation surface of the mounting base in the container to a transportation surface of the external mounting base.

5. The energy-saving container-type data center according to claim 1, wherein at least one of a rack system, an uninterrupted power supply and distribution system, a battery system, a firefighting system, an access security system, power environment monitoring system, video monitoring system, integrated wiring system, network communication system, IT equipment system are integrated in a space of the container of the container-type data center.

6. The energy-saving container-type data center according to claim 1, wherein the container-type data center includes cabinets and the cabinets are configured to move forward and backward within a container of the container-type data center by a distance of not less than 100 mm.

7. An energy-saving container-type data center according to claim 1, wherein an airflow management system is arranged in a container of the container-type data center, and the airflow management system isolates a cold airflow from a hot airflow in the container.

8. The energy-saving container-type data center according to claim 7, wherein an air supply type of the integrated air-conditioning system is lower air supply and upper return air, and the airflow management system isolates an air supply vent of the lower air supply from a return air vent of the upper return air, and the cold air flow is enclosed in a space at a front of a cabinet, and the hot airflow flows from a rear of the cabinet through a top of the cabinet to the return air vent.

9. The energy-saving container-type data center according to claim 7, wherein an air supply type of the integrated air-conditioning system is lower air supply and upper return air, and the airflow management system includes a hot aisle cavity at a rear of a cabinet, a return air channel above the cabinet, and an airflow assembly connected to a return air vent of the upper return air, and the hot airflow at the rear of the cabinet flow to the air return vent through a top of the cabinet.

10. The energy-saving container-type data center of claim 7, wherein an air supply type of the integrated air conditioning system is upper air supply and lower return air, the airflow management system isolates a return air vent of the lower return air from an air supply vent of the upper air supply, and the hot airflow is enclosed in a space at a rear of a cabinet, the hot airflow enters the return air vent from the rear of the cabinet, and the cold air flow from the air supply vent enters a front of the cabinet through a top of the cabinet.

11. The energy-saving container-type data center according to claim 7, wherein an air supply type of the integrated air-conditioning system is upper air supply and lower return air, and the air flow management system includes a cold aisle cavity at a front of a cabinet, an air supply channel above the cabinet, and an airflow assembly connected to an air supply vent of the upper air supply, and the cold airflow from the air supply vent flows to the front of the cabinet through a top of the cabinet.
